(19) United States
(12) Patent Application Publication
(10) Pub. No.: US 2011/0031510 A1
(43) Pub. Date: Feb. 10, 2011

(54) ENCAPSULATED LENS STACK

(75) Inventors: Markus Rossi, Jona (CH); Hartmut Rudmann, Jona (CH); Ville Kettunen, Ruschlikon (CH)

Correspondence Address: RANKIN, HILL & CLARK LLP, 38210 GLENN AVENUE, WILLOUGHBY, OH, 44094-7808, US

(73) Assignee: HEPTAGON OY, Espoo (FI)

(21) Appl. No.: 12/744,833

(22) PCT Filed: Nov. 18, 2008
(86) PCT No.: PCT/CH2008/000487

§ 371 Date: Oct. 22, 2010

Related U.S. Application Data
(60) Provisional application No. 60/990,451, filed on Nov. 27, 2007.

(51) Int. Cl. H01L 33/58; H01L 31/0232; H01L 31/18

(52) U.S. Cl. 257/88; 257/432; 438/27; 438/65; 257/E33.056; 257/E31.127

(57) ABSTRACT

A wafer scale package includes two or more substrates (wafers) that are stacked in an axial direction and a plurality of replicated optical elements. An optical device includes one or more optical elements. The wafer scale package and the device include one or more cavities that house the optical elements, while the end faces of the package or the device are planar and do not have replicated optical elements thereon. The number of double sided substrates is reduced, and design and manufacture of the optical device is improved.

### BACKGROUND OF THE INVENTION

1. Field of the Invention

The invention is in the field of manufacturing integrated optical devices with two or more optical elements, e.g. refractive and/or diffractive lenses, in a well defined spatial arrangement on wafer scale by means of a replication process. Such integrated optical devices are, for example, camera devices, optics for camera devices, or collimating optics for flash lights, especially for camera mobile phones. More concretely, the invention relates to a wafer scale package comprising two or more substrates (wafers) that are stacked in an axial direction and have a plurality of replicated optical elements. The invention further relates to an optical device, e.g. a camera or a collimating optics therefor, comprising two or more replicated optical elements and optionally also electro-optical components, to a method for production of such a wafer scale package, and to a method of manufacturing a plurality of optical elements.

2. Description of Related Art

Manufacture of optical elements by replication techniques, such as embossing or molding, is known. Of special interest for a cost effective mass production are wafer-scale manufacturing processes where an array of optical elements, e.g. lenses, is fabricated on a disk-like structure (wafer) by means of replication. In most cases, two or more wafers with optical elements attached thereto are stacked in order to form a wafer scale package where optical elements attached to different substrates are aligned. Subsequent to replication, this wafer structure can be separated into individual optical devices (dicing).

Replication techniques include injection molding, roller hot embossing, flat-bed hot embossing, UV embossing. As an example, in the UV embossing process, the surface topology of a master structure is replicated into a thin film of a UV-curable replication material such as an UV curable epoxy resin on top of a substrate. The replicated surface topology can be a refractive or a diffractive optically effective structure, or a combination of both. For replicating, a replication tool bearing a plurality of replication sections that are a negative copy of the optical structures to be manufactured is prepared, e.g. from a master. The tool is then used to UV-emboss the epoxy resin. The master can be a lithographically fabricated structure in fused silica or silicon, a laser or e-beam written structure, a diamond turned structure or any other type of structure. The master may also be a submaster produced in a multi stage generation process by replication from a (super) master.

A wafer or substrate in the meaning used in this text is a disc or a rectangular plate or a plate of any other shape of any dimensionally stable, often transparent material. The diameter of a wafer disk is typically between 5 cm and 40 cm, for example between 10 cm and 31 cm. Often it is cylindrical with a diameter of either 2, 4, 6, 8 or 12 inches, one inch being about 2.54 cm. The wafer thickness is for example between 0.2 mm and 10 mm, typically between 0.4 mm and 6 mm.

If light needs to travel through the wafer, the wafer is at least partially transparent. Otherwise, the wafer can be nontransparent as well. It can also be a wafer bearing electro-optical components, e.g. a silicon or GaAs or other semiconductor based wafer; it may for example be a CMOS wafer or a wafer carrying CCD arrays or an array of Position Sensitive Detectors, a wafer carrying light sources such as LEDs or VECSELs, etc.

The wafer-scale replication allows the fabrication of several hundreds of generally identical devices with a single step, e.g. a single or double-sided UV-embossing process. The subsequent separating (dicing) step of the wafer then yields the individual optical devices.

Integrated optical devices include functional elements, at least one of which is an optical element, stacked together along the general direction of light propagation. Thus, light travelling through the device passes through the multiple elements sequentially. These functional elements are arranged in a predetermined spatial relationship with respect to one another (integrated device) such that further alignment with themselves is not needed, leaving only the optical device as such to be aligned with other systems.

Such optical devices can be manufactured by stacking wafers that comprise functional, e.g. optical, elements in a well defined spatial arrangement on the wafer. Such a wafer scale package (wafer stack) comprises at least two wafers that are stacked along the axis corresponding to the direction of the smallest wafer dimension (axial direction) and attached to one another. At least one of the wafers bears replicated optical elements, and the other can comprise or can be intended to receive optical elements or other functional elements, such as electro-optical elements. The wafer stack thus comprises a plurality of generally identical integrated optical devices arranged side by side. Precise positioning of the optical/functional elements on the different wafers, but also within the same wafer, is essential for the performance of the individual integrated devices. Subsequent dicing of the stack then yields the individual integrated optical devices.

By spacer means, e.g. a plurality of separated spacers or an interconnected spacer matrix as disclosed in US 2003/0010431 or WO 2004/027880, the wafers can be spaced from one another, and optical elements can also be arranged between the wafers on a wafer surface facing another wafer.

Wafer scale packages as presently known generally comprise two or more substrates that have optical elements arranged on both of their main surfaces. Such substrates are also designated as double-sided wafers/substrates. The optical elements are, for example, convex or concave structures, each forming a classical refractive (half-) lens. For optical design purposes, each pair of such structures/half-lenses on both sides of the wafer can be treated as a single classical lens with two convex/concave surfaces, for example. Generally, when trying to fulfill given performance requirements, the aim is to keep the optical design as simple as possible by reducing the number of lenses and to keep manufacture as simple and well-priced as possible by reducing the number of substrates. As a consequence, all designs actually employed in integrated devices use double-sided wafers, wherein empty surfaces are generally avoided.

An example for an optical device 1 manufactured from such a package according to the prior art is shown in FIG. 7. It comprises two (double-sided) substrate portions 2, 3, each having optical elements 4 on both sides. Each pair 4′ of optical elements 4 acts as single classical convex lens. The substrate portions 2, 3 are stacked in axial direction Z and spaced by spacer means 5. The finished stack is placed on top of a further substrate 6, e.g. a CMOS wafer. To avoid mechanical damage of the optical element 4, which is arranged on the bottom of the stack and which faces the further substrate 6, and to allow attachment of the stack to the further substrate 6, further spacer means 7 are arranged in between the bottom substrate 3 and the further substrate 6.

The following problems arise when manufacturing or handling such packages or devices:

The freely accessible optical elements on the end faces of the package are subject to damage or contamination by dust or an adhesive, especially during the dicing step and/or when further components like a camera or a flash light or other (opto-) electronic components are attached to the wafer scale package or the individual optical device. Protective hoods or cover plates or additional spacer means as described with respect to FIG. 7 may thus be needed. Such hoods or cover plates or spacers make the design of the module more complicated and costly. Especially hoods may also adversely affect the optical properties of the device.

Another problem is associated with the manufacture of double-sided wafers in a replication process. In a double sided substrate with optical structures on both main surfaces, it is necessary that the optical structures on both sides are precisely aligned with respect to one another. Consequently, the substrate has to be precisely aligned two times with respect to the replication tool, in a first step for replication of the structures on one surface and in a second step for replication of the structures on the second surface. Alignment in the second step is especially difficult, because of the structures already present on the other surface.

A further problem is that the substrates need a certain thickness to ensure stability during replication. Especially when replicating on the second surface, the substrate cannot be supported over its entire area due to the structures on the first surface.

There are further limitations associated with the present design. As discussed above, the optical structures on a double sided substrate can be considered as a single (double sided) lens. The optical parameters of this lens are influenced by the thickness of the substrate, and this thickness generally cannot be changed. Further, an aperture stop of common packages or devices, if any, normally coincides with the plane of one of the lenses. This is a restriction of the design possibilities and may also lead to unwanted collection of stray light into the device.

### BRIEF SUMMARY OF THE INVENTION

It is therefore an objective of the present invention to provide a wafer scale package as well as an optical device that overcomes the above mentioned problems and is easier to manufacture than known packages or devices having the same functionality. It is a further objective of the invention to provide a wafer scale package as well as an optical device ensuring protection of all optical elements from damage or contamination. It is a further objective of the invention to provide a wafer scale package as well as an optical device that is easy to manufacture and provides more freedom of design.

The wafer scale package according to the invention comprises at least two outer substrates and optionally one or more intermediate substrates stacked in an axial direction (perpendicular to the main surfaces of the substrates). A plurality of preferably closed cavities is arranged in between the substrates. In case of two substrates, there is one layer or group of cavities, in case of n substrates, there are generally n-1 or less groups or layers of cavities. Replicated optical elements, e.g. classical convex/concave lenses or diffractive/refractive microstructures, attached to the inner surfaces of the substrates, are arranged within the cavities. At least one pair of neighboring substrates of the package has optical elements on each of the surfaces which face one another. In other words, each cavity located in between this pair of substrates comprises two optical elements. Preferably, these optical elements are axially aligned.

The minimum wafer stack consists of two single sided substrates, i.e. substrates with replicated optical elements only on one of their main surfaces. The substrates are arranged such that the optical elements face one another, and the distance between them is defined by spacer means which may be a separate element or an integral part of one or both of the substrates. The outer surfaces of the substrates, i.e. the end faces of the package/stack do not comprise any replicated optical elements. Typically, there is also at least one intermediate substrate, again spacer separated. This intermediate substrate is preferably, but not necessarily double sided, i.e. comprises optical elements on both of its surfaces. The top substrate is typically a transparent wafer with optical elements on its inner surface. The bottom substrate may be a transparent substrate with or without optical elements, or it may be a substrate carrying an array of electro-optical components, in particular imaging elements (cameras, CCD, Position Sensitive Detectors) or light sources (LEDs or VECSELs etc.); for this purpose, silicon or GaAs or other semiconductor based (e.g. CMOS) wafers can be used.

According to the invention, the outer surfaces of the outer substrates and thus the end faces of the package and the optical device do not comprise any replicated optical elements. Thus, no replicated optical elements are exposed to the exterior. All optical elements are arranged in between the outer surfaces of the outer substrates, as seen in the axial direction. The end faces of the wafer stack are generally unstructured and planar. They may, however, contain apertures and/or alignment marks that leave the generally planar surface unchanged. They may also contain a coating such as an IR cutoff filter or an anti reflection coating. Such elements may be applied at a later stage after replication and stacking is completed.

The invention uses a completely different approach than in state-of-the-art designs as discussed in the introduction:

According to the invention, the lens of conventional designs—a double sided lens formed by optical structures on both surfaces of a transparent substrate (double sided substrate)—is split in two “halves” by having two substrates with optical structures on only one surface and a planar other surface. There are, thus, two single sided substrates instead of one double sided substrate, and the order of the “halves” is reversed. This means that the individual thickness of the two “halves” as well as their distance can be chosen individually and, thus, opens up new design degrees of freedom. The optical elements are shaped and arranged in such a way that the same optical performance as with the double sided lens is achieved. As there are no limitations with respect to the shape, thickness and distance of the optical elements, an even better performance can be achieved. This splitting generally concerns the outermost lens as seen in the axial direction. Intermediate substrates, if present, may be double-sided.

The invention makes possible that in integrated optical devices, especially, no lens is present on the outermost surface, i.e. the surface that is most remote from the active (e.g. CMOS) device. This is in contrast to the prior art, where the total number of wafers is minimized by using as many double-sided substrates as possible. Here, the outer substrates are single-sided or do not comprise any optical elements at all, e.g. in case of a CMOS wafer as bottom substrate of the stack. In other words, in contrast to the state of the art, the invention dispenses with an especially shaped refractive (or possibly diffractive) surface on the outermost layer that according to the state of the art was considered essential for achieving the best performance. This has the advantage that all optical elements are arranged in between the unstructured end faces of the system as seen in axial direction. They are, thus, protected from damage or contamination during manufacture and handling. The planar end faces simplify manufacture and handling as well as the optical design of the package. Nevertheless, not much additional space/additional elements is/are required. For example, in contrast to state-of-the art solutions, both, the lowermost and the topmost element of the assembly have a flat surface and may be assembled to rest directly against a surface of an other part—thus no additional, external spacers are required, sometimes even space saving and part saving solutions are possible. The latter is especially (also) suited for cases where passive and active optical components are manufactured at different places, as the stack with just passive optical components comprises no outermost lenses, it can be shipped without any sophisticated packaging protection (the protection is an intrinsical property of the wafer scale package and of the individual optical devices), and it can nevertheless be, in the final assembly, no more spacious than prior art assemblies.

In general, the inventive wafer scale package ensures a well defined spatial arrangement of the replicated optical elements and, optionally, by means of integrating a semiconductor substrate into the package further electro-optical components, as well as the simultaneous production of a plurality of identical optical devices with very small dimensions and at low cost. All optical elements are well protected during manufacture and handling, especially during the step of dicing the package into individual optical devices.

These and further beneficial effects will be described in more detail below.

Preferably, the cavities are closed such that all optical elements are fully encapsulated by the substrate and/or the spacer means also in a lateral direction. This can be achieved by using spacer means or recesses having an appropriate shape, e.g. through-holes in an otherwise continuous substrate.

The cavities are formed by connecting two neighboring substrates via spacer means, e.g. a plurality of separated spacers or an interconnected spacer matrix as disclosed in US 2003/0010431 or WO 2004/027880, and/or by using one or more preshaped substrates with a plurality of recesses.

The claimed optical device may be manufactured by dicing the wafer scale package described above. It is thus suited for mass production. It comprises at least two outer substrate portions stacked in an axial direction with at least one preferably closed cavity in between the substrate portions. The cavity is formed e.g. by using spacer means or a preshaped substrate, as described above. The device further comprises two optical elements, arranged in the at least one cavity. The optical device comprises two essentially planar end faces that are constituted by outer surfaces of the outer substrate portions. All optical elements are, thus, well protected.

In a preferred embodiment, the optical device is made of a wafer scale package with three or more substrates and, thus, comprises at least one intermediate substrate portion arranged in between the outer substrate portions, and two or more preferably axially aligned cavities spaced from one another by the intermediate substrate portion(s). The intermediate substrate portion(s) is/are preferably double sided, i.e. comprise(s) optical elements on both surfaces, while the outer substrate portions are single sided. The bottom substrate may be a substrate with electro-optical components, like an imaging device or light sources, on its inner surface. These components are also arranged within a preferably closed cavity and thus well protected. For example, the optical device may be a camera with integrated optics which can be mass produced at low cost, e.g. for the use in mobile phones.

The method for producing a wafer scale package comprises the following steps: Providing at least two substrates; providing said at least two substrates with a plurality of optical elements by means of a replication technique; stacking the at least two substrates in an axial direction; and connecting the at least two substrates in such a way that cavities enclosing the optical elements are formed, wherein end faces of the package are essentially planar and are constituted by outer surfaces of outer substrates of the package.

The method for producing an optical element, in particular a camera, comprises the steps of the method for producing a wafer scale package and further the step of dicing the package along planes running in axial direction in order to separate the package into individual optical elements. Preferably, dicing takes place along planes running through the spacer means such that the cavities in the individual devices remain closed and the optical elements arranged therein fully encapsulated.

The Invention has the Following Advantages:

Optical Design:
As discussed above, in current stacks the aperture stop is always in the same plane with one of the lenses. The encapsulated wafer stack according to the invention has two “free” end faces and thus allows the aperture to be also in a different plane, e.g. in either of the flat end surfaces. This leads to more design flexibility.
Since the two out-most wafers are at most single sided and allow attaching of a carrier/support wafer for added stability during replication (and its removal after replication), thinner wafers can be used. This also leads to more design flexibility.
If the aperture stop is placed on the top surface, the encapsulated stack is less sensitive to stray-light since there is no lens before the aperture to also “collect” unwanted light into it, leading to an improved performance.
Especially for, but not limited to, singlets (bi-convex or bi-concave lenses formed on a double sided substrate), the encapsulated design according to the invention (two single sided substrates at a distance from one another) gives better performance, especially in terms of the modulation transfer function (MTF) in the corner of the field (i.e. resolution in the corner) and in terms of field curvature (i.e. separation in the z-position of the on-axis and off-axis image planes). Latter is good for focus free designs. The better performance is primarily obtained by the fact that the encapsulated case allows the distance between the two lens surfaces to be a free parameter, while in a normal case, one is forced to stay with distances that are available as standard wafers.
In addition, in the encapsulated case the refraction in the flat (top) surface can be to some extent utilized, while in the case of normal design, the refraction at the cover glass is completely fixed by the need to match the chief ray angles at the sensor. In other words, while both configurations have three surfaces (two lenses and one flat surface), the order of surfaces is beneficial with the encapsulated case. This would be a similar effect than e.g. the difference seen in focusing performance of a plano-convex singlet depending on the lens orientation.

Mechanical design, especially if the optical device is used in a camera module:
Since none of the lenses is exposed, a separate plastic hood is not needed to protect the lenses. The module design is thus simplified, and costs are saved.
If nevertheless a plastic hood is used, reduced sensitivity to stray-light makes the shape and size of the aperture in the hood less critical, leading also to a simplified module design.

Stack Manufacturing & Module Assembly:
As discussed above, the manufacture of double sided substrates is complicated because the substrate has to be precisely aligned with respect to the replication tool. The invention allows reduction of the number of aligned double sided replications, and thus simplifies fabrication of the device.
As the lenses are preferably fully encapsulated, no foreign materials or chemicals can get to the lenses. The wafer package and the optical device are thus less sensitive to assembly conditions. Also, standard cleaning processes can be used in case the top or bottom end faces are dirty.
The end faces of the package are flat, which allows easier handling during dicing and bonding. The packages and devices are also easier to handle, especially with fully automated systems.
The encapsulation of the lenses offers added reliability in the form of protection against environmental conditions. This means that the range of suitable replication materials and coatings etc. is larger.
The encapsulation offers added mechanical protection of the replicated optical elements. The package may thus be even suited for insert molding.

One preferred application of the inventive optical device is for CMOS cameras, including CMOS cameras for mobile phones. Here, one of the flat and unstructured end faces could be directly used as the cover window of the camera, of a module within the camera, or even of the phone cover instead of a separate cover window. This leads to both simplified assembly and lower material cost.

### BRIEF DESCRIPTION OF THE DRAWINGS

FIG. 1 shows schematically a wafer scale package with two substrates spaced by spacer means;

FIG. 2 shows schematically an optical device manufactured by dicing a package as shown in FIG. 1;

FIG. 3 shows schematically a wafer scale package with two substrates, one of them pre-shaped;

FIG. 4 shows schematically a wafer scale package with three substrates spaced by spacer means;

FIG. 5 shows schematically an optical device manufactured by dicing a package as shown in FIG. 4, attached to a further wafer, e.g. CMOS wafer;

FIG. 6 shows an optical device similar to that of FIG. 5 with a CMOS wafer as a bottom substrate;

FIG. 7 shows schematically an optical device according to the prior art.

### DESCRIPTION OF THE PREFERRED EMBODIMENTS

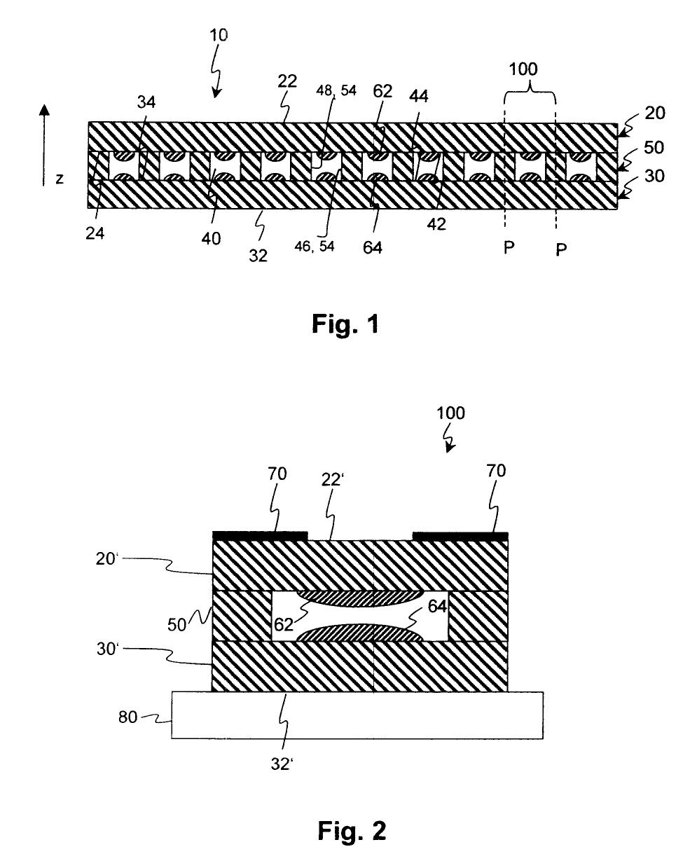

FIG. 1 shows, purely schematically, an embodiment of a wafer scale package according to the invention 10 with two planar outer substrates 20, 30, which are preferably standard wafers, and a plurality of cavities 40 in between the substrates 20, 30. The outer substrates 20, 30 are stacked in a direction z normal to their main surfaces 22, 24, 32, 34, which is also designated as the axial direction. The substrates 20, 30 are axially spaced by spacer means 50.

The axial walls 42, 44, i.e. in FIG. 1 the bottom and top walls, of the cavities 40 are constituted by portions of the inner surfaces 24, 34 of the two outer substrates 20, 30. The lateral walls 46, 48 of the cavities 40 are constituted by the corresponding lateral walls 54 of the spacer means 50. The spacer means 50 are constituted by a flat substrate with a plurality of through-holes (spacer matrix), for example, or by individual spacers.

Optical elements 62, 64 are attached to the inner surfaces 24, 34 of the substrates 20, 30 at places corresponding to the locations of the cavities 40, and more particular, at places corresponding to the bottom and top walls 42, 44 of the cavities 40. The outer surfaces 22, 32 of the top and bottom substrate 20, 30 do not comprise optical elements. Consequently, each cavity 40 houses two optical elements 62, 64 such that they are encapsulated as seen in the axial direction. Preferably, the spacer means are shaped such that the optical elements 62, 64 are also encapsulated as seen in the lateral direction, such that all optical elements 62, 64 present are fully encapsulated and protected.

In this example, the optical elements 62 attached to the top substrate 20 are aligned with respect to the optical elements 64 from the bottom substrate 30 in the same cavity 40; other embodiments include also off-axis arrangements.

The package 10 shown in FIG. 1 may be manufactured by providing two standard substrates 20, 30. On each of the substrates 20, 30, optical elements 62, 64 are manufactured by means of a replication technique. In particular, portions of replication material are applied to the substrate on locations corresponding to the locations of the optical elements 62, 64 to be manufactured, and the optical elements are then formed by bringing a replication tool into close proximity with the substrate. As an alternative, the replication material may be applied directly onto the replication tool. The replication tool has structural features corresponding to the outer shape of the optical element. Hardening the replication material with the structure of the replication tool imprinted then yields the optical elements.

The package 10 shown in FIG. 1 is an alternative solution to a single double sided wafer with optical elements on both main surfaces. Alignment problems during the replication of the optical elements on one and the same wafer are avoided, as single sided wafers are used. The encapsulated stack according to the invention comprises more wafers than the known double sided solution. However, it is not necessarily thicker, as the wafers can be supported by a planar support during replication and can thus generally be made thinner than double sided wafers that need to have a certain stability for replication on both sides.

Individual optical devices 100 are manufactured by dicing the wafer scale package 10 along axial planes P. An example for an optical device 100 manufactured from a package as shown in FIG. 1 is illustrated in FIG. 2. It comprises outer substrate portions 20′, 30′ corresponding to the outer substrates 20, 30 of the package 10. As the axial planes P run through the spacer means 50, the optical elements 62, 64 remain fully encapsulated by the top and bottom substrate portions 20′, 30′ and the spacer means 50 also in the individual optical device 100.

The individual optical device 100 may optionally be attached to a further substrate 80, e.g. a CMOS wafer carrying electronic components like an optical sensor, or a cover glass in case of a packaged sensor. Since the bottom end face 32′ of the bottom substrate portion 30′ is planar, attachment of the further substrate 80 is particularly easy, and there is also no danger of exposing the optical elements 62, 64 to any substances that might damage them when attaching the further substrate 80.

Instead of attaching the further substrate to the diced optical element 100, it may also be attached to the wafer package 10 prior to the dicing step, e.g. as disclosed in WO 2005/083789 which is incorporated herein by reference. This further simplifies manufacture.

An aperture 70 may be attached to or manufactured on the top end face 22′ of the optical device 100 or already on the top end face 22 of the package 10. As shown in FIG. 2, the aperture 70 lies in a different plane than both optical elements 62, 64. This allows for more freedom of design.

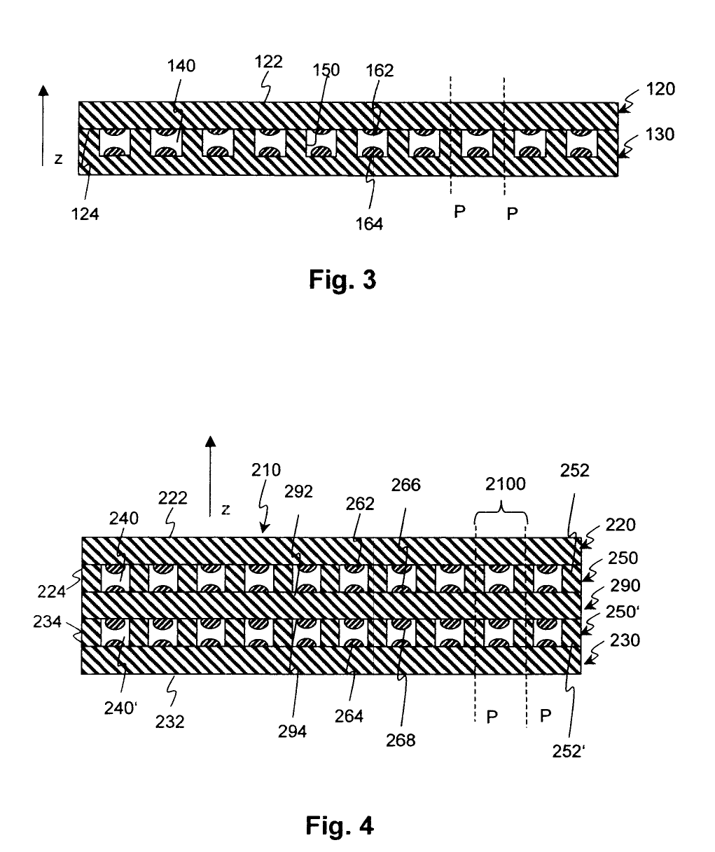

FIG. 3 shows a further embodiment of the invention. The wafer scale package 110 comprises two outer substrates 120, 130. The top substrate 120 is a standard substrate with planar surfaces 122, 124. The bottom substrate 130 is pre shaped and comprises a planar outer surface 132 and an inner surface 134 that is structured by a plurality of recesses 150 (or having the spacer means as an integral part of the bottom substrate 130). The recesses 150 are shaped such that a plurality of cavities 140 is formed when connecting the top substrate 120 directly to the bottom substrate 130.

Like in FIG. 1, a plurality of optical elements 162 is attached to the inner surface 124 of the top substrate 120 at locations corresponding to those of the cavities 140 and the recesses 150, respectively. Furthermore, optical elements 164 are arranged at the bottoms of the recesses 150 of the pre shaped substrate 130 in axial alignment with the optical elements 162 on the top substrate 120. Like in FIG. 1, all optical elements 162, 164 are fully encapsulated, and the end faces are planar and without optical elements.

Dicing of stack 110 along the planes P again yields the individual optical devices (not shown).

FIG. 4 shows a further embodiment 210 of the invention with two outer substrates 220, 230, and one intermediate substrate 290, stacked in axial direction Z. Two layers of cavities 240, 240′ are arranged between the top substrate 220 and the intermediate substrate 290, and the intermediate substrate 290 and the bottom substrate 230, respectively. The cavities 240, 240′ are formed by means of two sets of spacer means 250, 250′ arranged between the respective substrates.

As with the embodiments described above, the top and bottom substrates 220, 230 are single sided and comprise optical elements 262, 264 only on their inner surfaces 224, 234, while the outer surfaces 222, 232 and, thus, the end faces of the stack 210 are planar and without optical elements. The intermediate substrate 290 is double sided and comprises optical elements 266, 268 on both of its main surfaces 292, 294. The cavities 240, 240′ of the two layers are axially aligned with respect to one another. Within the cavities, the optical elements are also axially aligned; off-axis arrangements (not shown) are possible. Again, all optical elements are fully encapsulated. The individual optical devices 2100 are produced by dicing along the planes P.

Though one double sided substrate 290 is present in the embodiment of FIG. 4, the total number of double sided substrates is reduced by one as compared to the prior art (FIG. 6) for the same number of optical elements, thus reducing the effort in connection with double sided replication of optical elements on wafers.

For more complicated optical devices, further single or double sided intermediate substrates and corresponding spacer means may be incorporated into the stack.

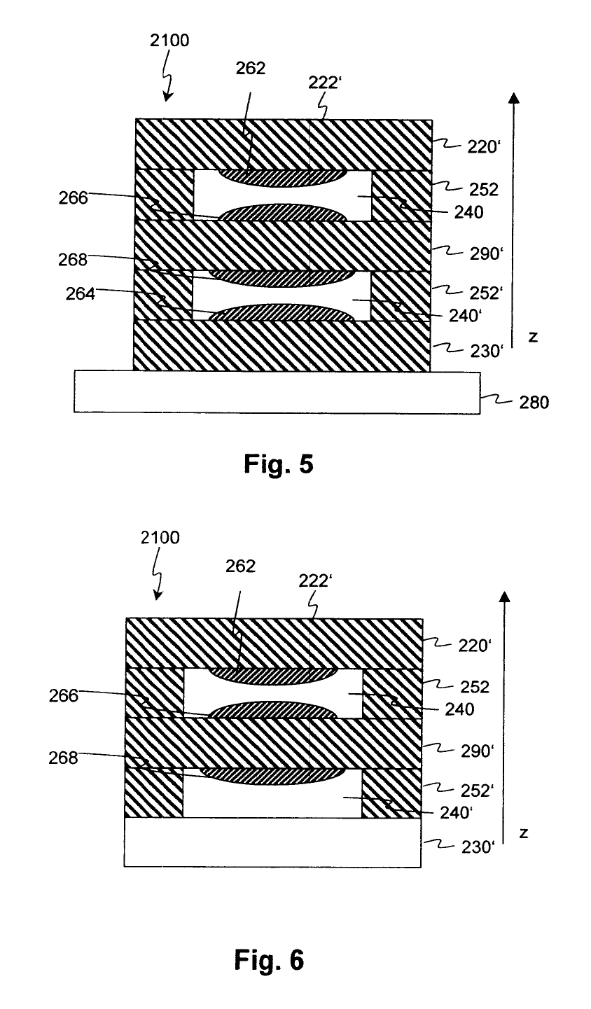

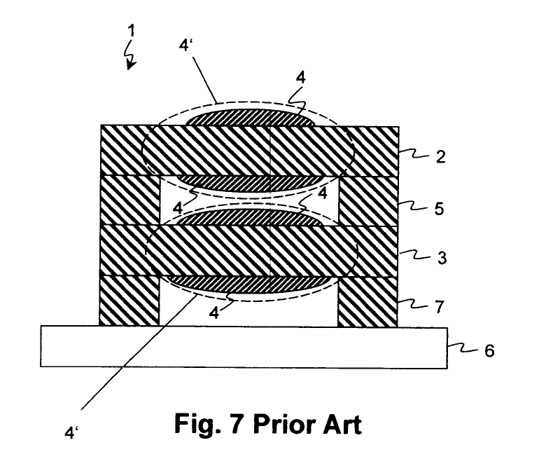

FIG. 5 shows an integrated optical device 2100 manufactured by dicing from a stack 210 as shown in FIG. 4. The top and bottom outer substrate portions 220′, 230′ and intermediate substrate portion 290′are stacked in axial direction Z and spaced by spacers 252, 252′, i.e. portions of the spacer means 250, 250′ from FIG. 4, such that two cavities 240, 240′ are formed. The cavities 240, 240′ house the optical elements 262, 266, 264, 268 described in connection with FIG. 4. The optical elements 262, 266, 264, 268 may be convex or concave lenses, or may comprise micro-optical structures that represent a predetermined optical function.

The end faces 222′, 232′ do not comprise replicated optical structures, however. they may receive some sort of finishing treatment, e.g. polishing, attachment of apertures, attachment of a further substrate 280, like a CMOS wafer or a cover class. The further substrate 280 can be attached prior to or after dicing.

FIG. 6 shows an optical device similar to that of FIG. 5. The difference it that the bottom outer substrate portion 230′ is constituted by a portion of a CMOS or other semiconductor wafer. This portion 230′ preferably bears electro-optical components, like an imaging element. The bottom substrate 230, here e.g. the CMOS wafer, is attached to the stack prior to dicing. The optical element 268 in the lower cavity 264 as well as any electro-optical components on the bottom substrate portion 230′ are thus well protected by the lateral walls of the cavity (the spacer means) and the adjoining substrate portions 230′, 290′.

1. Wafer scale package, comprising:
at least two outer substrates stacked in an axial direction,
a plurality of cavities in between the substrates, and a plurality of replicated optical elements arranged the cavities,
wherein at least two optical elements are arranged in one common cavity at a distance from one another as seen in the axial direction, and
wherein the package comprises two essentially planar end faces that are constituted by outer surfaces of the outer substrates.

2. Wafer scale package as claimed in claim 1, wherein the cavities are closed and all optical elements present are arranged in the cavities.

3. Wafer scale package as claimed in claim 1 or 2, further comprising spacer means spacing the substrates from one another in order to form the cavities in between the substrates.

4. Wafer scale package as claimed in claim 3, wherein the spacer means are represented by a spacer substrate with a plurality of through-holes.

5. Wafer scale package as claimed in claim 1, wherein at least one of the substrates is preshaped and comprises a front face and a rear face, at least one of said front face and rear face comprising a plurality of recesses in order to form the cavities in between the substrates.

6. Wafer scale package as claimed in claim 1, further comprising at least one intermediate substrate arranged in between the outer substrates such that at least two groups of cavities arranged in different planes are formed in between the substrates.

7. Wafer scale package as claimed in claim 6, wherein the cavities of each group are aligned as seen in the axial direction and wherein optical elements are arranged on both surfaces of the intermediate substrate and are aligned as seen in the axial direction.

8. Wafer scale package as claimed in claim 6, wherein one of the outer substrates is a semiconductor based substrate.

9. Wafer scale package as claimed in claim 6, wherein a semiconductor based substrate is attached to one of the end faces of the outer substrates, over the entire area of said end face.

10. Wafer scale package as claimed in claim 8, wherein the semiconductor based substrate comprises an array of imaging elements or an array of light sources.

11. Optical device comprising.;
at least two outer substrate portions stacked in an axial direction,
at least one cavity in between the substrate portions, and
at least two replicated optical elements arranged in the at least one cavity at a distance from one another as seen in the axial direction,
wherein the optical device comprises two essentially planar end faces that are constituted by outer surfaces of the outer substrate portions.

12. Optical device as claimed in claim 11, further comprising spacer means spacing the substrate portions from one another in order to form the at least one cavity in between the substrate portions.

13. Optical device as claimed in claim 11, wherein at least one of the substrate portions is preshaped and comprises a recess in order to form the at least one cavity in between the substrates.

14. Optical device as claimed in claim 11, further comprising at least one intermediate substrate portion arranged in between the outer substrate portions such that at least two cavities arranged in different planes as seen in the axial direction are formed in between the substrate portions.

15. Optical device as claimed in claim 14, wherein the cavities are aligned as seen in the axial direction and wherein optical elements are arranged on both surfaces of the intermediate substrate portion and are aligned as seen in the axial direction.

16. Method for producing a wafer scale package comprising the steps of:
providing two substrates, each having an inner surface and an outer surface;
providing the inner surfaces of the substrates with a plurality of optical elements by means of a replication technique, while leaving the outer surfaces empty;
stacking the at least two substrates in an axial direction such that the inner surfaces and the optical elements thereon face one another;
connecting the outer substrates to form a package in such a way that cavities are formed in between the outer substrates, each cavity enclosing at least two optical elements at a distance from one another as seen in the axial direction, wherein end faces of the package are essentially planar and are constituted by the outer surfaces of the outer substrates.

17. Method according to claim 16, further comprising the step of providing at least one intermediate substrate.

18. Method according to claim 17, further comprising the step of providing the at least one intermediate substrate with optical elements on both of its surfaces by means of a replication technique in such a way that the optical elements on the surfaces of the intermediate substrate are aligned as seen in the axial direction.

19. Method according to claim 17, wherein one of the outer substrates is a semiconductor based substrate, having a plurality of imaging elements or light sources.

20. Method according to claim 17, further comprising the step of attaching a semiconductor based substrate to one of the end faces of the outer substrates, preferably over the entire area of said end face.

21. Method according to claim 16, further comprising the step of arranging spacer means in between two substrates in order to space the substrates from one another and to form the cavities in between the substrates.

22. Method according to claim 16, wherein at least one of the substrates is a preshaped substrate with a plurality of recesses, and wherein the step of connecting the at least two substrates comprises connecting the preshaped substrate directly to another substrate such that the cavities are formed in the regions of the recesses.

23. Method for producing an optical element, in particular a camera, comprising the steps of the method according to claim 16 and further comprising dicing the package along planes running in axial direction in order to separate the package into individual optical elements.

24. Method according to claim 23, wherein the planes run through the spacer means in order to form optical devices having closed cavities.
